(19) United States
(12) Patent Application Publication
(10) Pub. No.: US 2015/0060124 A1
(43) Pub. Date: Mar. 5, 2015

(54) COMBINED PRINTED WIRING BOARD AND METHOD FOR MANUFACTURING THE SAME

(71) Applicant: IBIDEN CO., LTD., Ogaki (JP)

(72) Inventors: Makoto TERUI, Ogaki (JP); Takashi KARIYA, Ogaki (JP); Yoshinori SHIZUNO, Ogaki (JP); Masatoshi KUNIEDA, Ogaki (JP)

(73) Assignee: IBIDEN CO., LTD., Ogaki (JP)

(21) Appl. No.: 14/473,235

(22) Filed: Aug. 29, 2014

(30) Foreign Application Priority Data
Aug. 31, 2013 (JP) 2013-180791

(51) Int. Cl. H05K 1/11; H05K 3/20; H05K 3/40; H05K 1/02

(52) U.S. Cl. CPC H05K 1/111; H05K 1/0298; H05K 3/20; H05K 3/4007; H05K 2201/10159; H05K 2201/10007; H05K 2201/094
USPC 174/261; 29/831

(57) ABSTRACT

A combined printed wiring board includes a multilayer printed wiring board having an outermost insulation layer, and a wiring film fixed to a portion of the outermost insulation layer of the multilayer printed wiring board. The wiring film includes dense-pitch pads formed on a semiconductor-mounting surface of the wiring film, the multilayer printed wiring board has sparse-pitch pads formed on a semiconductor-mounting surface of the multilayer printed wiring board, the dense-pitch pads are formed to facilitate electrical connection between a first semiconductor element and a second semiconductor element, and the sparse-pitch pads are formed to facilitate electrical connection between the multilayer printed wiring board and the first semiconductor element and/or the second semiconductor element.

### CROSS-REFERENCE TO RELATED APPLICATIONS

The present application is based upon and claims the benefit of priority to Japanese Patent Application No. 2013-180791, filed Aug. 31, 2013, the entire contents of which are incorporated herein by reference.

### BACKGROUND OF THE INVENTION

1. Field of the Invention

The present invention relates to a combined printed wiring board, more specifically, to a printed wiring board with a basic structure made of a organic material (epoxy resin, for example), which has dense-pitch pads to make it capable of mounting a semiconductor element. The present invention also relates to a method for manufacturing such a printed wiring board.

2. Description of Background Art

In circuit boards to be used for electronic devices such as personal computers and server computers, memory elements (DRAM, for example) and logic elements (CPU, MPU and the like, for example) are mounted on separate wiring boards.

### SUMMARY OF THE INVENTION

According to one aspect of the present invention, a combined printed wiring board includes a multilayer printed wiring board having an outermost insulation layer, and a wiring film fixed to a portion of the outermost insulation layer of the multilayer printed wiring board. The wiring film includes dense-pitch pads formed on a semiconductor-mounting surface of the wiring film, the multilayer printed wiring board has sparse-pitch pads formed on a semiconductor-mounting surface of the multilayer printed wiring board , the dense-pitch pads are formed to facilitate electrical connection between a first semiconductor element and a second semiconductor element, and the sparse-pitch pads are formed to facilitate electrical connection between the multilayer printed wiring board and the first semiconductor element and/or the second semiconductor element.

According to another aspect of the present invention, a method for manufacturing a combined printed wiring board includes forming a wiring film including dense-pitch pads formed on a semiconductor-mounting surface of the wiring film, and fixing the wiring film to a portion of an outermost insulation layer of a multilayer printed wiring board such that the wiring film and the multilayer printed wiring board are formed to have electrical connection. The multilayer printed wiring board includes sparse-pitch pads formed on a semiconductor-mounting surface of the multilayer printed wiring board, the dense-pitch pads are formed to facilitate electrical connection between a first semiconductor element and a second semiconductor element, and the sparse-pitch pads are formed to facilitate electrical connection between the multilayer printed wiring board and the first semiconductor element and/or the second semiconductor element.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view illustrating the structure of a combined printed wiring board according to an embodiment of the present invention;

FIG. 1B is an enlarged view of a portion of the structure of a combined printed wiring board according to the embodiment, to illustrate the connection between semiconductor elements, a second wiring board and a first wiring board;

FIG. 1C is a schematic view further illustrating the connection between semiconductor elements, a second wiring board and a first wiring board;

FIG. 2 is a cross-sectional view of a second wiring board (wiring film) of the embodiment;

FIG. 3A is a view illustrating a first method for planarizing tips (top portions) of solder bumps on the semiconductor mounting surface of the combined printed wiring board according to the embodiment;

FIG. 3B is a view illustrating a second method for planarizing tips (top portions) of solder bumps on the semiconductor mounting surface of the combined printed wiring board according to the embodiment;

FIG. 4A is a view, along with other views, illustrating a step for manufacturing a second wiring board according to the embodiment;

FIG. 4B is a view, along with other views, illustrating a step for manufacturing a second wiring board according to the embodiment;

FIG. 4C is a view, along with other views, illustrating a step for manufacturing a second wiring board according to the embodiment;

FIG. 4D is a view, along with other views, illustrating a step for manufacturing a second wiring board according to the embodiment;

FIG. 4E is a view, along with other views, illustrating a step for manufacturing a second wiring board according to the embodiment;

FIG. 4F is a view, along with other views, illustrating a step for manufacturing a second wiring board according to the embodiment;

FIG. 4G is a view, along with other views, illustrating a step for manufacturing a second wiring board according to the embodiment;

FIG. 4H is a view, along with other views, illustrating a step for manufacturing a second wiring board according to the embodiment;

FIG. 4I is a view, along with other views, illustrating a step for manufacturing a second wiring board according to the embodiment;

FIG. 4J is a view, along with other views, illustrating a step for manufacturing a second wiring board according to the embodiment;

FIG. 4K is a view, along with other views, illustrating a step for manufacturing a second wiring board according to the embodiment;

FIG. 4L is a view, along with other views, illustrating a step for manufacturing a second wiring board according to the embodiment;

FIG. 5A is a view, along with other views, illustrating a step for manufacturing a first wiring board according to the embodiment;

FIG. 5B is a view, along with other views, illustrating a step for manufacturing a first wiring board according to the embodiment;

FIG. 5C is a view, along with other views, illustrating a step for manufacturing a first wiring board according to the embodiment;

FIG. 5D is a view, along with other views, illustrating a step for manufacturing a first wiring board according to the embodiment;

FIG. 5E is a view, along with other views, illustrating a step for manufacturing a first wiring board according to the embodiment;

FIG. 5F is a view, along with other views, illustrating a step for manufacturing a first wiring board according to the embodiment;

FIG. 5G is a view, along with other views, illustrating a step for manufacturing a first wiring board according to the embodiment;

FIG. 5H is a view, along with other views, illustrating a step for manufacturing a first wiring board according to the embodiment;

FIG. 6A is a view showing an example that replaces the step for manufacturing a first wiring board illustrated in FIG. 5A; and

FIG. 6B is a view showing an example that replaces the step for manufacturing a first wiring board illustrated in FIG. 5B.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

### Structure of Combined Printed Wiring Board

To facilitate an understanding of a first embodiment, characteristics of a combined printed wiring board are briefly provided first.

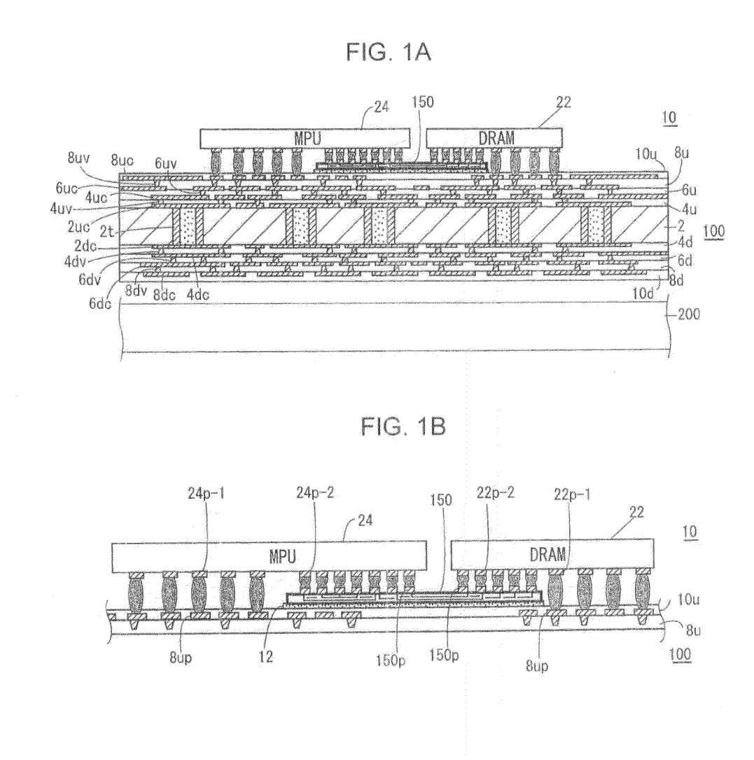

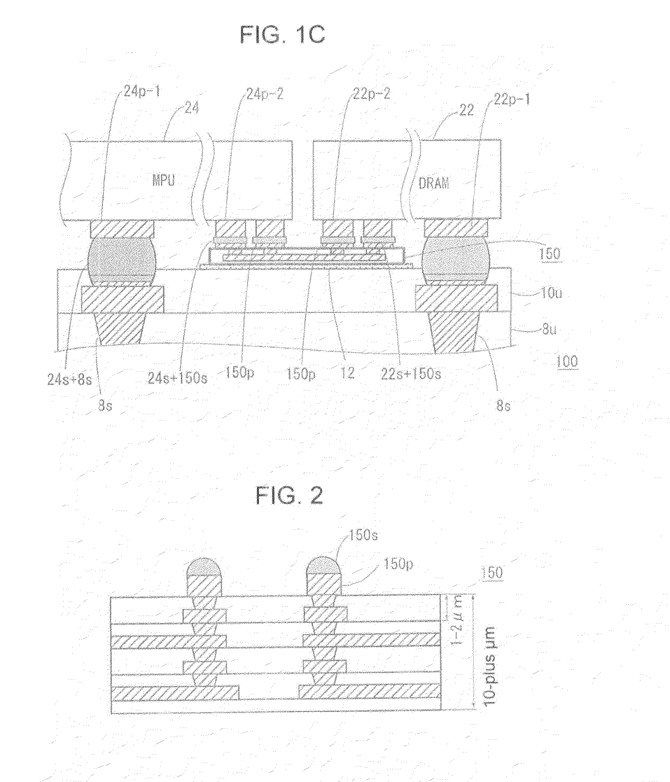

FIG. 1A is a cross-sectional view illustrating the structure of combined printed wiring board 10 according to the first embodiment. Combined printed wiring board 10 mounts first and second semiconductor elements (22, 24) on one of its main surfaces and is connected to motherboard 200 on the other main surface. Connections between combined printed wiring board 10 and first and second semiconductor elements (22, 24) are made by solder bumps using flip-chip mounting technology. Connection between combined printed wiring board 10 and motherboard 200 is carried out, for example, by solder bumps, and by pin connection through stud pins formed on either side, or the like. Combined printed wiring board 10 is formed by combining two wiring boards.

First wiring board 100 is an organic multilayer printed wiring board, for example. The present embodiment shows an example where a triple-layered buildup layer is formed on each of both surfaces of a core substrate. However, that is not the only option, and first wiring board 100 may be any type of multilayer printed wiring boards.

Regarding a printed wiring board such as first wiring board 100, typically, its line and space (hereinafter referred to as “L/S”) of circuit patterns is set at approximately 15 μm/15 μm, 10 μm/10 μm, or the like. Generally speaking, the L/S of an organic printed wiring board is set at 10 μm/10 μm or greater for reasons of manufacturing technology. Accordingly, its pads are “sparse-pitch pads.”

Second wiring board 150 is a wiring film (also referred to as a “wiring structure” or a “thin substrate”) fixed onto the outermost layer of the semiconductor-element mounting surface of first wiring board 100. As described by referring to FIG. 2, wiring film 150 is a double-layered or multilayered wiring board formed to be a thin film and has circuit patterns formed using a semiconductor manufacturing process. Thus, as for the L/S of its circuit patterns, typically, fine patterns such as 5 μm/5 μm, 3 μm/3 μm, 2 μm/2 μm or 1.5 μm/1.5 μm can be formed. Namely, the L/S of second wiring board 150 can be set at less than 10 μm/10 μm. Thus, its pads are set as “dense-pitch pads.”

First wiring board 100 and second wiring board 150 are manufactured separately, and then are combined to form combined printed wiring board 10.

Parts of the pads of semiconductor elements (22, 24) are electrically connected to the pads of second wiring board 150, and the rest of the pads are electrically connected to the pads of first wiring board 100. Namely, second wiring board 150 is positioned in part of the space between first wiring board 100 and semiconductor elements (22, 24).

Next, each structural component is described with reference to the accompanying drawings.

### First Wiring Board

First wiring board (printed wiring board) 100 shown in FIG. 1 may be any multilayer printed wiring board. Typically, first wiring board 100 is a multilayer printed wiring board made of organic material (epoxy resin, for example). Thus, its description is brief here. In first wiring board 100 as shown in FIG. 1, core substrate 2, through-hole conductor (2t) and conductive layers (2uc, 2dc) of the core substrate are formed. Core substrate 2 may be a multilayer wiring board manufactured using, for example, a subtractive method, semi-additive method, full-additive method or the like.

Since FIG. 1 has numerous details, its reference numerals are described. In FIG. 1, on both surfaces of core substrate 2, reference numeral 4 is assigned for a first layer, reference numeral 6 for a second layer and reference numeral 8 for a third layer. Moreover, an affix (u) is added to the components positioned above core substrate 2, and an affix (d) is added to those positioned below core substrate 2. In addition, an affix (v) is added to via conductors and an affix (c) is added to conductive layers.

On both surfaces of core substrate 2, first interlayer resin insulation layers (4ui, 4di) having first via conductors (4uv, 4dv) and second conductive layers (4uc, 4dc) are formed respectively. In addition, second interlayer resin insulation layers (6ui, 6di) having second via conductors (6uv, 6dv) and second conductive layers (6uc, 6dc) are formed respectively on first interlayer resin insulation layers (4ui, 4di), and third interlayer resin insulation layers (8ui, 8di) having third via conductors (8uv, 8dv) and third conductive layers (8uc, 8dc) are formed respectively on second interlayer resin insulation layers (6ui, 6di). Moreover, solder-resist layers or insulation resin layers (10ui, 10di) are respectively formed on third interlayer resin insulation layers (8ui, 8di).

First wiring board 100 may be a coreless wiring board without having a core substrate, and the number of buildup layers is not limited to the above and may be any other number.

The L/S of first wiring board 100 is set at 10 μm/10 μm or greater, since it is a typical printed wiring board made of organic material. Thus, its pads are “sparse-pitch pads,” for example, at a pitch of 100 μm or greater.

### Second Wiring Board

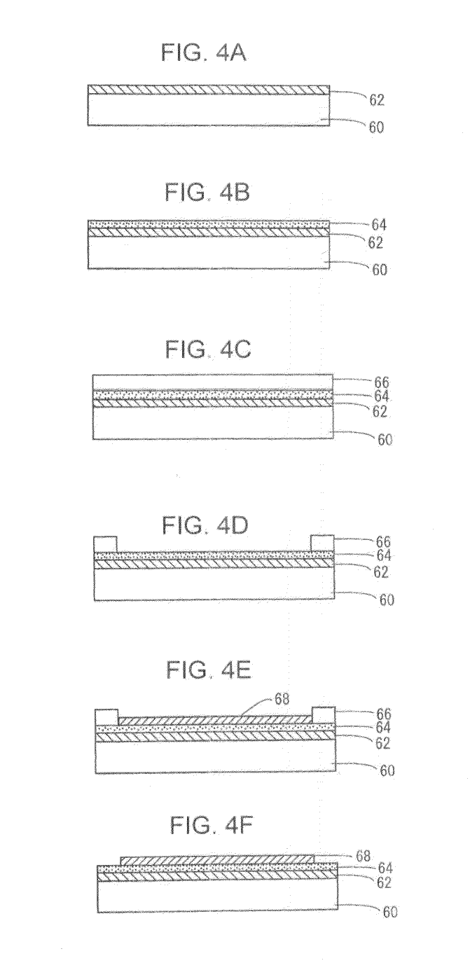

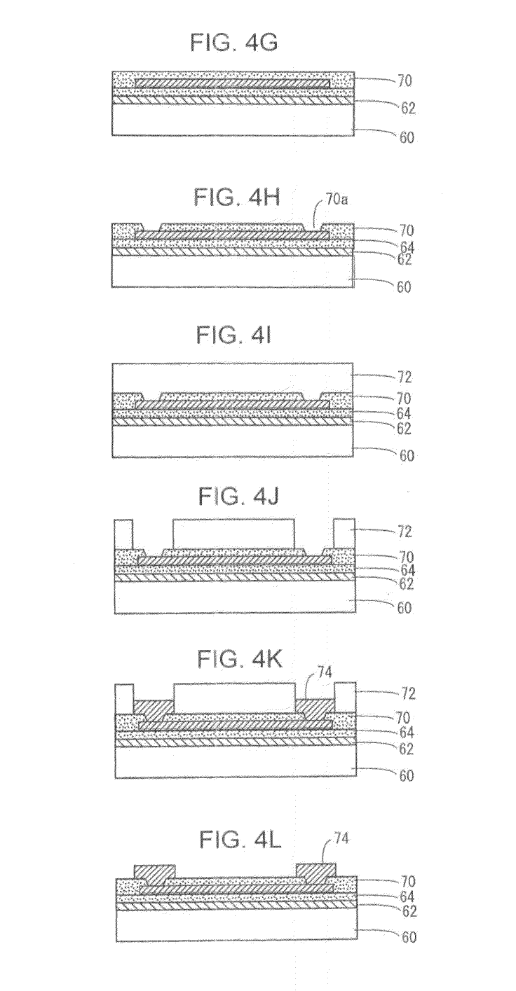

Second wiring board (wiring film) 150 is a very thin film-type wiring board manufactured separately. As described with reference to FIG. 4A˜4K, using a semiconductor process, double-layered or multilayered circuit patterns are formed on a silicon- or glass-sheet carrier, which is removed later. Thus, the L/S of the circuit patterns can be set at less than 10 μm/10 μm, and the pads can also be formed as “dense-pitch pads.” For example, the pitch here is less than 100 μm.

As shown in FIG. 1B, second wiring board 150 is physically fixed through bonding material 12 to a portion of the semiconductor-element mounting surface of first wiring board 100 so as to form combined printed wiring board 10. On the semiconductor-element mounting surface of combined printed wiring board 10, first semiconductor element 22 and second semiconductor element 24 are mounted to be positioned side by side. Regarding each of first semiconductor element 22 and second semiconductor element 24, one portion is mounted on second wiring board 150 and the rest is mounted on first wiring board 100.

### Semiconductor Elements

FIG. 1A shows a DRAM as first semiconductor element 22 and an MPU as second semiconductor element 24. That is not the only example, but first semiconductor element 22 is usually set to be a semiconductor memory element whereas second semiconductor element 24 is a semiconductor logic element. Thus, in an example to be described here, a DRAM is set as first semiconductor element 22 and an MPU as second semiconductor element 24. In addition, two semiconductor elements are shown in FIG. 1A, but two or more semiconductor elements may also be mounted.

### Connection of Each Element

FIGS. 1B and 1C are each a partially enlarged view illustrating the connection between semiconductor elements, the second wiring board (wiring film) and the first wiring board (printed wiring board) in the structure of a combined printed wiring board according to the first embodiment.

When the focus is on second wiring board (wiring film) 150, the first wiring board side of second wiring board 150 is physically fixed to first wiring board 100 by bonding material 12. Bonding material 12 is made of, for example, underfill (UF), insulative film (UCF), adhesive agent or the like. Second wiring board 150 is fixed to first wiring board 100 by bonding material 12, and the space between them is encapsulated to avoid moisture or the like.

The pitches of pads formed on the semiconductor mounting surface of combined wiring board 10 are described below.

First, semiconductor elements are observed. Among the pads of DRAM 22, the pitch of pads (22p-1) for electrical connection with first wiring board 100 is sparse, whereas the pitch of pads (22p-2) for electrical connection with MPU 24 through second wiring board 150 is dense. In the same manner, among the pads of MPU 24, the pitch of pads (24p-1) for electrical connection with first wiring board 100 is sparse, whereas the pitch of pads (24p-2) for electrical connection with DRAM 22 through second wiring board 150 is dense.

To correspond to the pad pitches of semiconductor elements, pads (150p) formed on the semiconductor-element mounting surface of second wiring board (wiring film) 150 are set to be dense-pitch pads.

Next, when the focus is on first wiring board (printed wiring board) 100, all pads (8up) are sparse-pitch pads, and its circuit patterns are also formed to be sparse. To correspond to the pad pitch of first wiring board 100, pads (22p-1, 24p-1) of semiconductor elements (22, 24) to be electrically connected to the first wiring board are set to be sparse-pitch pads.

Regarding the pad pitches of semiconductor elements, those shown in the drawings can be employed for a logic element, responding to a user's need. Also, a side-by-side mounting type memory element may employ the pad pitches shown in the drawings to achieve high-speed interface with a logic element.

Among the pads of DRAM 22, pads (22p-2) for electrical connection with MPU 24 are formed to be positioned closer to MPU 24 as shown in the drawings. In the same manner, among the pads of MPU 24, pads (24p-2) for electrical connection with DRAM 22 are formed to be positioned closer to DRAM 22.

Generally, in electronic components such as personal computers and server computers, a program and data are transferred in response to a job command from a high-capacity memory device (HDD, for example) (not shown) with a relatively slow read/write capability to a semiconductor element with a relatively small capacity but with a high-speed read/write capability (memory element 22, for example), and the program is further transferred to logic element 24. To execute the program, data are sequentially called from memory element 22 to logic element 24 and computed, and the computation results are transferred from logic element 24 to be written sequentially to memory element 22. After the job is completed, the processed results are transferred to the high-capacity memory device. As described, while data are processed, data are transferred frequently in large quantities between memory element 22 and logic element 24.

Accordingly, as shown in the drawings, in an example where DRAM 22 and MPU 24 are mounted to be connected by second wiring board 150, pads of each element are formed in close proximity to each other. Such a mounting example is especially preferable since the distance from the pads of one element to the pads of another element (namely, wiring length in second wiring board 150) is reduced, and signal transmission lag is thereby further shortened. Since second wiring board 150 is formed using a semiconductor manufacturing process, fine patterns are formed.

### Second Wiring Board

FIG. 2 is a cross-sectional view of second wiring board (wiring film) 150. Second wiring board 150 currently under study is a film-type wiring board where the thickness of each insulation layer is set at 2˜4 μm and the entire thickness of all the insulation layers is set at 10˜20 μm. the upper surface of the second wiring board, solder balls (150s) are formed for connection with semiconductor elements (here, solder balls are not formed depending on mounting methods to be employed). No circuit pattern is formed on the lower surface of second wiring board 150.

### Planarizing Heights of Solder Bumps

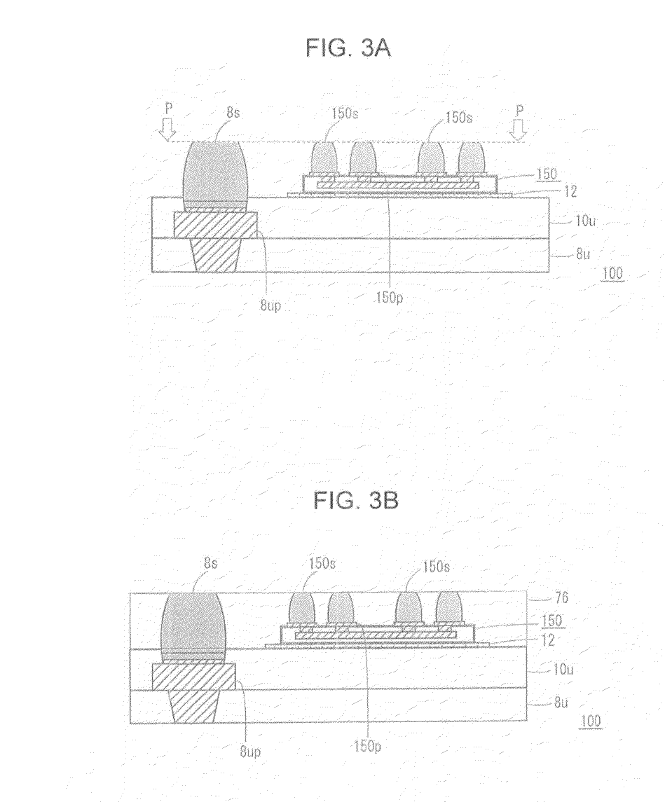

As shown in FIG. 3A, the distance to semiconductor elements (22, 24) (see FIG. 1B) is different from pad (8up) of first wiring board 100 and from pad (150p) of second wiring board 150. When mounting semiconductor elements (22, 24), it is preferred to even out the tips (top portions) of solder bump (8s) formed on pad (8up) and the tip (top portion) of solder bump (150s) formed on pad (150p). FIG. 3A shows a method for planarizing the heights by pressurizing tips of solder bumps (8s, 150s) using a metal plate with a flat surface (not shown).

FIG. 3B shows a method for planarizing the heights of solder bumps as follows: resin insulation layer 76 is formed on a surface of first wiring board 100 where solder bumps (8s, 150s) are formed; and portions of solder bumps (8s, 150s) protruding from the resin insulation layer are planarized by polishing, pressurizing or blasting. Molded underfill, non-conductive film (NCF) generally without filler, underfill (UF) resin generally containing filler or the like may be used for resin insulation layer 76.

### Method for Manufacturing Second Wiring Board

Methods for manufacturing second wiring boards (wiring films) (150, 155) are described according to first and second embodiments by referring to FIG. 4A˜4L.

As shown in FIG. 4A, a support sheet (also referred to as a carrier) 60 is prepared. Typically, a support sheet is a flat silicon or glass sheet. Removable layer 62 is formed on its top surface. Removable layer 62 is formed so that a second wiring board formed on the support sheet can be removed from the support sheet at the final stage of the manufacturing process.

As shown in FIG. 4B, insulation layer 64 is formed on removable layer 62. For example, a thin insulation layer is formed by spinning.

As shown in FIG. 4C, by sputtering or the like, a seed layer is formed on insulation layer 64, and then photoresist 66 is formed. As practiced in a regular semiconductor process, liquid resist 66 is coated by spinning, for example, and is dried and cured.

As shown in FIG. 4D, using an appropriate mask (not shown), resist 66 is patterned. Namely, resist 66 is removed from portions for forming circuit patterns.

As shown in FIG. 4E, conductive layer 68 is formed on portions for forming conductive patterns. Namely, by sputtering or vacuum deposition used in a semiconductor manufacturing process, a seed layer is formed on the insulation layer where conductive patterns are to be formed. Then, using the seed layer as an electrode, electrolytic copper plating is performed. The semiconductor manufacturing process allows the formation of fine conductive patterns.

As shown in FIG. 4F, resist 66 is removed. Accordingly, lowermost conductive pattern 68 is formed. Lowermost conductive pattern 68 is positioned on insulation layer 64.

As shown in FIG. 4G, insulation layer 70 is further formed by spinning, for example. That is the same step as that described with reference to FIG. 4B.

As shown in FIG. 4H, via-conductor hole (70a) is formed in insulation layer 70 by a photolithographic process, for example.

As shown in FIG. 4I, after a seed layer is formed on the insulation layer with hole (70a) by sputtering or the like, photoresist 72 is formed. That is the same step as that described with reference to FIG. 4C.

As shown in FIG. 4J, photoresist 72 is patterned using an appropriate mask (not shown). That is the same step as that described with reference to FIG. 4D.

As shown in FIG. 4K, conductive layer 74 is formed where circuit patterns (including via conductors) are formed. That is the same step as that described with reference to FIG. 4E.

As shown in FIG. 4L, photoresist 72 is removed. That is the same step as that described with reference to FIG. 4F.

When it is a multilayer wiring board, steps described with reference to FIG. 4G˜4L are repeated a desired number of times. After the desired number of layers is formed, removable layer 62 is peeled off support sheet 60 at the final step. Second wiring board 150 is completed when removable layer 62 is removed.

### Method for Manufacturing First Wiring Board (Printed Wiring Board)

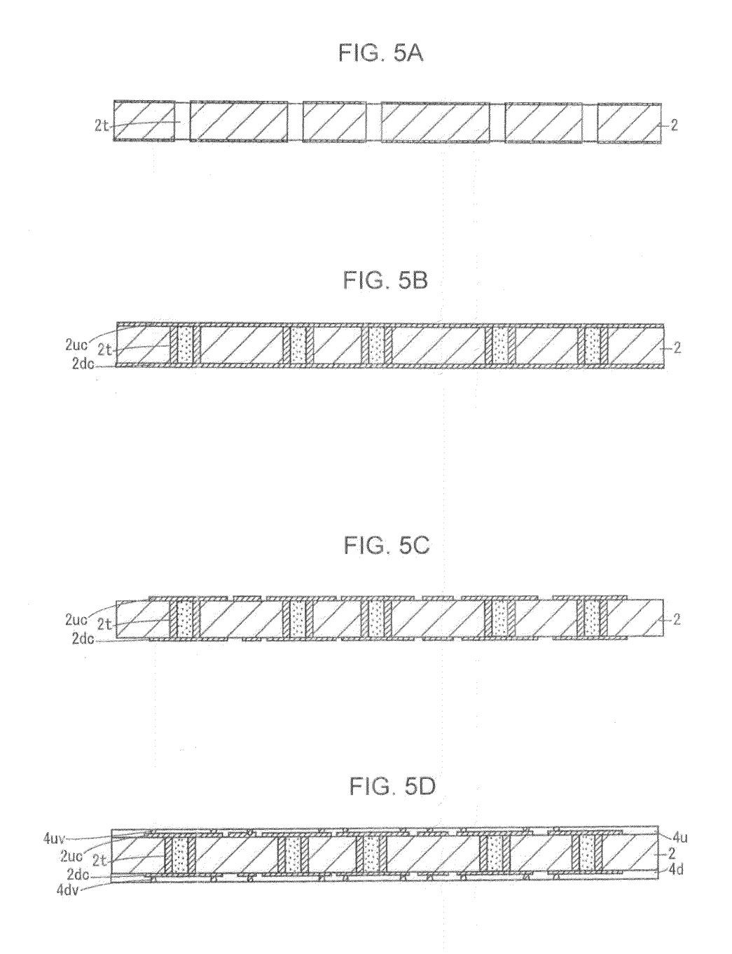

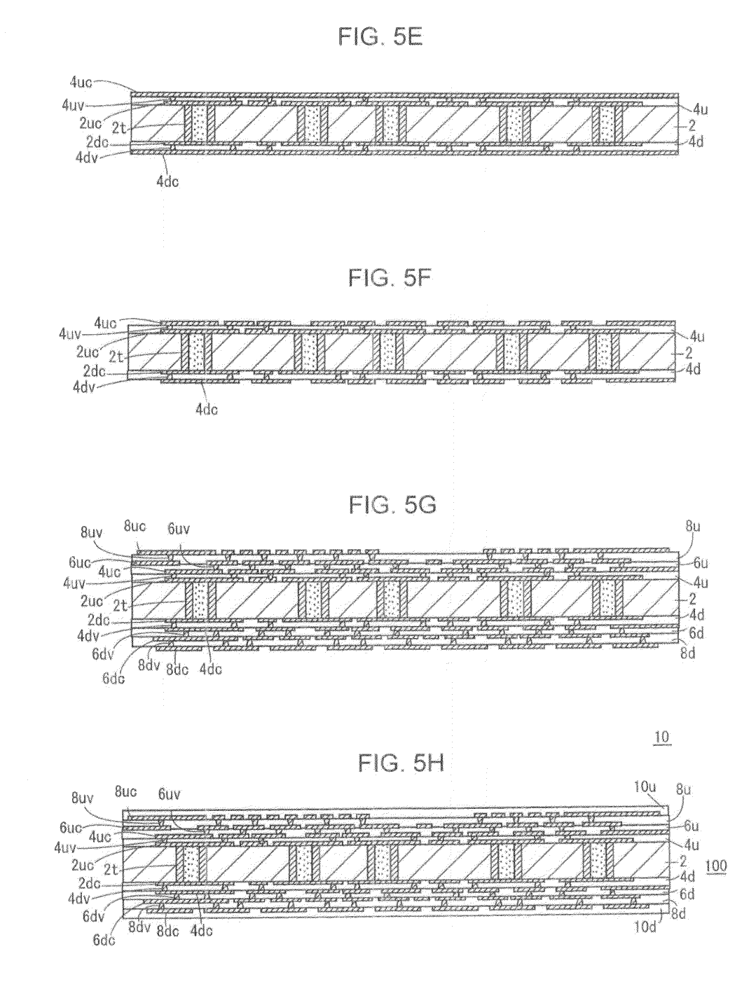

As first wiring board 100, any printed wiring board made of organic material (epoxy resin, for example) may be used. In the first embodiment shown in FIGS. 1A and 1B and in the second embodiment shown in FIGS. 3A and 3B, a wiring board is shown as an example where a triple-layered buildup layer is formed on each of both surfaces of a core substrate. Thus, a method for manufacturing such a wiring board is briefly described by referring to FIG. 5A˜5H.

As shown in FIG. 5A, a double-sided copper-clad laminate made of epoxy resin, for example, is prepared, and through hole (2t) is formed by a laser. When a semi-additive method is employed, copper foil on both surfaces is thin.

As shown in FIG. 5B, electroless copper plating is performed on the entire surface including inside the through hole, and electrolytic copper plating is then performed. Accordingly, conductive layers (2uc, 2dc) are formed respectively.

As shown in FIG. 5C, using photosensitive dry film (not shown), the conductive layers are patterned so that first conductive layers (2uc, 2dc) are formed.

As shown in FIG. 5D, first interlayer insulation layers (4u, 4d) are respectively formed on both surfaces. Insulative sheet or prepreg is used and then hot pressed.

As shown in FIG. 5E, via-conductor holes are formed in first interlayer insulation layers (4u, 4d) using a laser, and electroless copper plating and electrolytic copper plating are performed consecutively on the entire surface including inside the holes so that via conductors (4uv, 4dv) and conductive layers (4uc, 4dc) are respectively formed.

As shown in FIG. 5F, conductive layers are patterned using photosensitive dry film (not shown) so that second via conductors (6uv, 6dv) and second conductive layers (6uc, 6dc) are respectively formed.

As shown in FIG. 5G, the steps in FIG. 5C˜FIG. 5F are repeated twice to form second interlayer resin insulation layers (6u, 6d) where second via conductors (6uv, 6dv) and second conductive layers (6uc, 6dc) are respectively formed, and to further form third interlayer resin insulation layers (8u, 8d) where third via conductors (8uv, 8dv) and third conductive layers (8uc, 8dc) are respectively formed.

As shown in FIG. 5H, solder-resist layers or resin insulation layers (10u, 10d) are respectively formed. It is an option to form or not to form solder-resist layers or insulative resin layers (10u, 10d). Thus, the surface of first wiring board 100 for connection with the second wiring board is a solder-resist layer, resin insulation layer (10u), or third interlayer resin insulation layer (8u).

### ALTERNATIVE EXAMPLES

In FIG. 5A, hole (2t) for a through hole is made by laser irradiation. Instead, an hourglass-shaped through-hole conductor may be formed using the following steps.

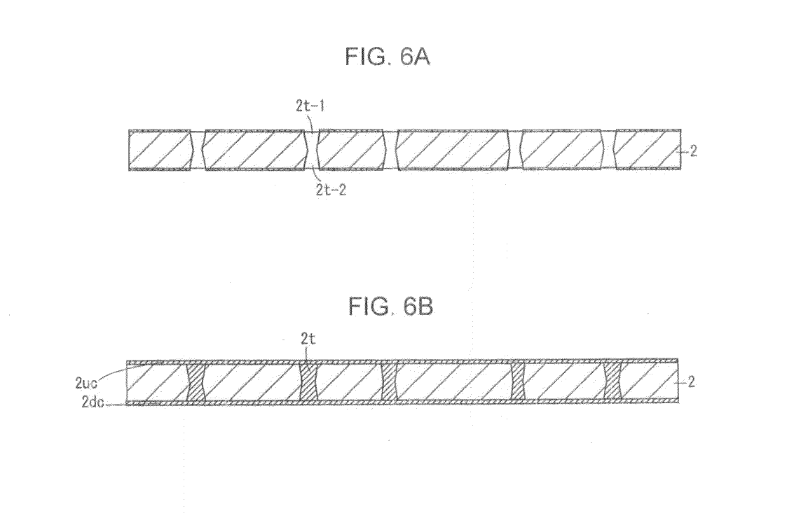

As shown in FIG. 6A, a laser is irradiated from the upper-surface side of a core substrate at a portion for forming a through hole to form first opening (2t-1) tapering with a diameter decreasing from the upper-surface side toward the lower-surface side. Then, a laser is irradiated from the lower-surface side at a portion for forming the through hole to form second opening (2t-2) tapering with a diameter decreasing from the lower-surface side toward the upper-surface side. Accordingly, an hourglass-shaped through hole made up of first opening (2t-1) and second opening (2t-2) is formed.

As shown in FIG. 6B, electroless copper plating followed by electrolytic copper plating is performed on the entire surface including first opening (2t-1) and second opening (2t-2). Accordingly, the hourglass-shaped through hole is filled with plating. Through-hole conductor (2t) and conductive layers (2uc, 2dc) are each formed.

The subsequent steps are the same as those described with reference to FIG. 5C˜5H.

### Combining First Wiring Board and Second Wiring Board

In combined printed wiring board 10 according to the first embodiment, first wiring board 100 and second wiring board 150, each formed separately, are physically fixed to each other by using bonding material 12.

As electronic devices are becoming faster, the speed of semiconductor elements increases and electrical signal transmission lag is reduced in wiring boards that electrically connect semiconductor elements to each other. Accordingly, a memory element and a logic element may be mounted in close proximity to each other (side by side) on one wiring board.

More specifically, in such a method, a separately manufactured silicon interposer may be mounted on a semiconductor-element mounting surface of a printed wiring board, and a memory element and a logic element may be arranged side by side on the other side of the silicon interposer. When an interposer is formed using a silicon substrate by a semiconductor manufacturing process, high-density circuit patterns corresponding to the patterns of semiconductor elements may be formed.

In such a silicon interposer, the pads on a surface facing semiconductor elements may be formed to have a relatively dense pitch so as to correspond to the dense-pitch pads of a semiconductor element, and the pads on the other surface facing a printed wiring board may be formed to have a relatively sparse pitch so as to correspond to sparse-pitch pads of the printed wiring board. Accordingly, the silicon interposer disposed between a printed wiring board and semiconductor elements works as a pitch converter. In the present application, typical pads in a printed wiring board are referred to as “sparse-pitch pads,” and typical pads in a semiconductor element are referred to as “dense-pitch pads.”

As described, when a silicon interposer is integrated, a printed wiring board becomes capable of responding to recent high-speed low-power consumption Wide I/O DRAMs (DRAMs where the number of data input/output terminals is widely expanded).

When a printed wiring board and a silicon interposer are combined, since silicon material may be used and the mounting process may be divided into two steps, such as mounting an interposer on a printed wiring board and mounting semiconductor elements on the interposer, the manufacturing cost becomes relatively high.

A printed wiring board with a structure made of an organic material (such as epoxy resin) according to an embodiment of the present invention has dense-pitch pads to make it capable of mounting semiconductor elements.

In a combined printed wiring board according to an embodiment of the present invention, a wiring film is fixed to a portion of the outermost insulation layer on one side of a multilayer printed wiring board. On the semiconductor-mounting surface of the wiring film, dense-pitch pads are formed for electrical connection between a first semiconductor element and a second semiconductor element, whereas on the semiconductor-mounting surface of the multilayer printed wiring board, sparse-pitch pads are formed to be used for electrical connection with the first semiconductor element or the second semiconductor element.

In addition, in the combined printed wiring board, the line and space of the dense-pitch pad region of the wiring film may be set at less than 10 μm/10 μm, whereas the line and space of the sparse-pitch pad region of the multilayer printed wiring board may be 10 μm/10 μm or greater.

Furthermore, in the combined printed wiring board, the pitch of the dense-pitch pads of the wiring film may be less than 100 μm, whereas the pitch of the sparse-pitch pads of the multilayer printed wiring board may be 100 μm or greater.

Yet furthermore, in the combined printed wiring board, the multilayer printed wiring board and the wiring film may be fixed to each other by any of (i) underfill, (ii) insulative film and (iii) insulative adhesive.

Yet furthermore, in the combined printed wiring board, the outermost insulation layer may be an interlayer insulation layer or a solder-resist layer.

Yet furthermore, in the combined printed wiring board, a first semiconductor element may be a semiconductor memory element and a second semiconductor element may be a semiconductor logic element.

Yet furthermore, in the combined printed wiring board, it is an option for a solder bump formed on a pad of the wiring film and a solder bump formed on the multilayer printed wiring board to be planarized so as to have the same height as each other.

Yet furthermore, in the combined printed wiring board, it is another option to set a structure as follows: a resin insulation layer is formed on a surface of the multilayer printed wiring board to which the wiring film is fixed; the tip of a solder bumps formed on a pad of the wiring film and the tip of a solder bumps formed on the multilayer printed wiring board are planarized; and the planarized portions are exposed at the surface of the resin insulation layer.

Yet furthermore, a method for manufacturing a printed wiring board according to an embodiment of the present invention is for forming a combined printed wiring board by manufacturing a multilayer printed wiring board using a printed wiring board manufacturing technology, by manufacturing a wiring film with patterns formed using a semiconductor manufacturing process, and by fixing the wiring film to a portion of the outermost layer of the multilayer printed wiring board. On the semiconductor-mounting surface of the wiring film, pads for electrical connection between a first semiconductor element and a second semiconductor element are set to be dense-pitch pads, whereas on the semiconductor-mounting surface of the multilayer printed wiring board, pads for electrical connection with a first or second semiconductor element are set to be sparse-pitch pads.

Yet furthermore, in the method for manufacturing a printed wiring board, it is an option for solder bumps on the pads of the wiring film and the solder bumps of the multilayer printed wiring board to be planarized so as to have the same height as each other.

Yet furthermore, in the method for manufacturing a printed wiring board, solder bumps on the pads of the wiring film and the solder bumps of the multilayer printed wiring board may be planarized by pressurizing the bumps using a flat-surface metal sheet.

Yet furthermore, in the method for manufacturing a printed wiring board, it is another option to form a resin insulation layer on the surface of the multilayer printed wiring board where the wiring film is fixed; and to planarize the tip of the solder bumps of the wiring film and the tip of the solder bumps of the multilayer printed wiring board, both protruding from the resin insulation layer, by polishing, pressurizing or blasting so as to expose the planarized portions on the surface of the resin insulation layer.

A printed wiring board with a structure made of an organic material according to an embodiment of the present invention has dense-pitch pads to make it capable of mounting semiconductor elements.

Obviously, numerous modifications and variations of the present invention are possible in light of the above teachings. It is therefore to be understood that within the scope of the appended claims, the invention may be practiced otherwise than as specifically described herein.

What is claimed is:

1. A combined printed wiring board, comprising:
a multilayer printed wiring board having an outermost insulation layer; and
a wiring film fixed to a portion of the outermost insulation layer of the multilayer printed wiring board,
wherein the wiring film includes a plurality of dense-pitch pads formed on a semiconductor-mounting surface of the wiring film, the multilayer printed wiring board has a plurality of sparse-pitch pads formed on a semiconductor-mounting surface of the multilayer printed wiring board, the plurality of dense-pitch pads is configured to facilitate electrical connection between a first semiconductor element and a second semiconductor element, and the plurality of sparse-pitch pads is configured to facilitate electrical connection between the multilayer printed wiring board and at least one of the first semiconductor element and the second semiconductor element.

2. A combined printed wiring board according to claim 1, wherein the plurality of dense-pitch pads of the wiring film is formed such that a line and space of the dense-pitch pads is less than 10 μm/10 μm, and the plurality of sparse-pitch pads of the wiring film is formed such that a line and space of the sparse-pitch pads is 10 μm/10 μm or greater.

3. A combined printed wiring board according to claim 1, wherein the plurality of dense-pitch pads of the wiring film is formed such that a pitch of the dense-pitch pads is less than 100 μm, and the plurality of sparse-pitch pads of the wiring film is formed such that a pitch of the sparse-pitch pads is 100 μm or greater.

4. A combined printed wiring board according to claim 1, wherein the wiring film is fixed onto the surface of the multilayer printed wiring board via one of an underfill, an insulative film and an insulative adhesive agent.

5. A combined printed wiring board according to claim 1, wherein the outermost insulation layer of the multilayer printed wiring board is one of an interlayer insulation layer and a solder resist layer.

6. A combined printed wiring board according to claim 1, wherein the first semiconductor element is a memory semiconductor element, and the second semiconductor element is a logic semiconductor element.

7. A combined printed wiring board according to claim 1, further comprising:
a plurality of first solder bumps formed on the multilayer printed wiring board; and
a plurality of second solder bumps formed on the dense-pitch pads and the sparse-pitch pads, respectively,
wherein the plurality of first solder bumps and the plurality of second solder bumps are planarized such that the first solder bumps and second solder bumps have a same height.

8. A combined printed wiring board according to claim 1, further comprising:
an insulation resin layer formed over the multilayer printed wiring board and the wiring film fixed on the multilayer printed wiring board;
a plurality of first solder bumps formed on the multilayer printed wiring board; and
a plurality of second solder bumps formed on the dense-pitch pads and the sparse-pitch pads, respectively,
wherein the plurality of first solder bumps and the plurality of second solder bumps are planarized such that the first solder bumps and second solder bumps have end portions exposed from the insulation resin layer.

9. A combined printed wiring board according to claim 7, wherein the plurality of dense-pitch pads of the wiring film is formed such that a line and space of the dense-pitch pads is less than 10 μm/10 μm, and the plurality of sparse-pitch pads of the wiring film is formed such that a line and space of the sparse-pitch pads is 10 μm/10 μm or greater.

10. A combined printed wiring board according to claim 7, wherein the plurality of dense-pitch pads of the wiring film is formed such that a pitch of the dense-pitch pads is less than 100 μm, and the plurality of sparse-pitch pads of the wiring film is formed such that a pitch of the sparse-pitch pads is 100 μm or greater.

11. A combined printed wiring board according to claim 7, wherein the wiring film is fixed onto the surface of the multilayer printed wiring board via one of an underfill, an insulative film and an insulative adhesive agent.

12. A method for manufacturing a combined printed wiring board, comprising:
forming a wiring film comprising a plurality of dense-pitch pads formed on a semiconductor-mounting surface of the wiring film; and
fixing the wiring film to a portion of an outermost insulation layer of a multilayer printed wiring board such that the wiring film and the multilayer printed wiring board are configured to have electrical connection,
wherein the multilayer printed wiring board includes a plurality of sparse-pitch pads formed on a semiconductor-mounting surface of the multilayer printed wiring board, the plurality of dense-pitch pads is configured to facilitate electrical connection between a first semiconductor element and a second semiconductor element, and the plurality of sparse-pitch pads is configured to facilitate electrical connection between the multilayer printed wiring board and at least one of the first semiconductor element and the second semiconductor element.

13. A method for manufacturing a combined printed wiring board according to claim 12, further comprising:
forming a plurality of first solder bumps on the multilayer printed wiring board;
forming a plurality of second solder bumps on the dense-pitch pads and the sparse-pitch pads, respectively; and
planarizing the plurality of first solder bumps and the plurality of second solder bumps such that the first solder bumps and second solder bumps have a same height.

14. A method for manufacturing a combined printed wiring board according to claim 13, wherein the planarizing of the first and second solder bumps includes pressing a flat-surface metal sheet against the first solder bumps on the multilayer printed wiring board and the plurality of second solder bumps on the dense-pitch and sparse pitch pads of the wiring film.

15. A method for manufacturing a combined printed wiring board according to claim 12, further comprising:
forming a plurality of first solder bumps on the multilayer printed wiring board;
forming a plurality of second solder bumps on the dense-pitch pads and the sparse-pitch pads, respectively;
forming an insulation resin layer over the multilayer printed wiring board and the wiring film fixed on the multilayer printed wiring board; and
planarizing the plurality of first solder bumps and the plurality of second solder bumps such that the first solder bumps and second solder bumps have end portions exposed from the insulation resin layer.

16. A method for manufacturing a combined printed wiring board according to claim 12, wherein the forming of the wiring film includes forming the plurality of dense-pitch pads of the wiring film such that a line and space of the dense-pitch pads is less than 10 μm/10 μm, and forming the plurality of sparse-pitch pads of the wiring film such that a line and space of the sparse-pitch pads is 10 μm/10 μm or greater.

17. A method for manufacturing a combined printed wiring board according to claim 12, wherein the forming of the wiring film includes forming the plurality of dense-pitch pads of the wiring film such that a pitch of the dense-pitch pads is less than 100 μm, and forming the plurality of sparse-pitch pads of the wiring film such that a pitch of the sparse-pitch pads is 100 μm or greater.

18. A method for manufacturing a combined printed wiring board according to claim 12, wherein the fixing of the wiring film includes applying one of an underfill, an insulative film and an insulative adhesive agent onto the portion of the outermost insulation layer of the multilayer printed wiring board such that the wiring film is fixed to the portion of the outermost insulation layer of the multilayer printed wiring board by one of the underfill, the insulative film and the insulative adhesive agent.

19. A method for manufacturing a combined printed wiring board according to claim 12, wherein the outermost insulation layer of the multilayer printed wiring board is one of an interlayer insulation layer and a solder resist layer.

20. A method for manufacturing a combined printed wiring board according to claim 12, wherein the forming of the wiring film includes forming a plurality of conductive patterns in the wiring film by a semiconductor manufacturing process such that the plurality of conductive patterns forms the dense-pitch pads.
